(19) United States
(12) Patent Application Publication
(10) Pub. No.: US 2024/0069106 A1
(43) Pub. Date: Feb. 29, 2024

(54) STORAGE BATTERY MANAGEMENT DEVICE AND STORAGE BATTERY MANAGEMENT METHOD

(71) Applicants: KABUSHIKI KAISHA TOSHIBA, Tokyo (JP); TOSHIBA ENERGY SYSTEMS & SOLUTIONS CORPORATION, Kawasaki-shi Kanagawa (JP)

(72) Inventors: Yukitaka MONDEN, Kawasaki Kanagawa (JP); Makoto IDE, Koganei Tokyo (JP); Masako KIUCHI, Fuchu Tokyo (JP); Mami MIZUTANI, Hachioji Tokyo (JP); Kenji MITSUMOTO, Setagaya Tokyo (JP); Takahiro KASE, Kawasaki Kanagawa (JP); Takenori KOBAYASHI, Meguro Tokyo (JP); Yoshihisa SUMIDA, Nakano Tokyo (JP)

(73) Assignees: KABUSHIKI KAISHA TOSHIBA, Tokyo (JP); TOSHIBA ENERGY SYSTEMS & SOLUTIONS CORPORATION, Kawasaki-shi Kanagawa (JP)

(21) Appl. No.: 18/261,243

(22) PCT Filed: Jan. 20, 2021
(86) PCT No.: PCT/JP2021/001914

§ 371 Date: Jul. 12, 2023

(51) Int. Cl. G01R 31/367; G01R 31/36; G01R 31/3842; G01R 31/389; H01M 10/42; H02J 7/00

(52) U.S. Cl. CPC G01R 31/367; G01R 31/3646; G01R 31/3842; G01R 31/389; H01M 10/425; H02J 7/0047; H01M 2010/4271

(57) ABSTRACT

A storage battery management device includes an acquisition unit, a selection unit, an estimation unit, and a display control unit. The acquisition unit acquires a battery characteristic and an operation condition of a storage battery device. The selection unit selects data values from a data value group of a data item in which variation in data value is caused out of data items included in the battery characteristic and the acquired operation condition. The estimation unit estimates, for each of the selected data values, a battery characteristic after operation corresponding to a case where the storage battery device is operated under the operation condition. The battery characteristic is estimated on the basis of the battery characteristic and the operation condition acquired by the acquisition unit. The display control unit displays the battery characteristic estimated by the estimation unit in a comparable state.

### CROSS-REFERENCE TO RELATED APPLICATIONS

This application is national stage application of International Application No. PCT/JP2021/001914, filed on Jan. 20, 2021, which designates the United States, incorporated herein by reference.

### FIELD

Embodiments described herein relate generally to a storage battery management device and a storage battery management method.

### BACKGROUND

Conventionally, a storage battery system including a plurality of storage battery modules has been used for various applications. In such a storage battery system, storage batteries constituting the storage battery modules have a battery characteristic such as a battery capacity that degrades (deteriorates) over time. The degree of deterioration of the storage battery also varies depending on a temperature of a use environment and an operation condition.

Therefore, conventionally, a technique of predicting a deterioration of a storage battery on the basis of conditions such as a temperature and a state of charge (SOC) has been proposed.

### BRIEF DESCRIPTION OF DRAWINGS

FIG. 1 is a diagram illustrating an example of a configuration of a storage battery system according to a first embodiment.

FIG. 2 is a diagram illustrating an example of a configuration of a storage battery unit according to the first embodiment.

FIG. 3 is a diagram for describing detailed configurations of a cell module, a CMU, and a BMU according to the first embodiment.

FIG. 4 is a diagram illustrating an example of a hardware configuration of a storage battery control device according to the first embodiment.

FIG. 5 is a diagram illustrating an example of a functional configuration of the storage battery control device according to the first embodiment.

FIG. 6 is a diagram for describing operation of a first battery characteristic estimation unit according to the first embodiment.

FIG. 7 is a diagram illustrating an example of a screen displayed by a display control unit according to the first embodiment.

FIG. 8 is a diagram illustrating another example of a screen displayed by the display control unit according to the first embodiment.

FIG. 9 is a diagram illustrating another example of a screen displayed by the display control unit according to the first embodiment.

FIG. 10 is a diagram illustrating an example of processing executed by the storage battery control device according to the first embodiment.

FIG. 11 is a diagram illustrating an example of a functional configuration of a storage battery control device according to a second embodiment.

FIG. 12 is a diagram illustrating an example of a screen displayed by a display control unit according to the second embodiment.

FIG. 13 is a diagram illustrating an example of processing executed by the storage battery control device according to the second embodiment.

FIG. 14 is a diagram illustrating an example of a functional configuration of a storage battery control device according to a third embodiment.

FIG. 15 is a diagram illustrating an example of processing executed by the storage battery control device according to the third embodiment.

FIG. 16 is a diagram illustrating an example of a configuration of a storage battery control device according to a first modification of the third embodiment.

### DETAILED DESCRIPTION

A storage battery management device according to one embodiment includes a hardware processor connected to a memory. The hardware processor is configured to function as an acquisition unit, a selection unit, and an estimation unit. The acquisition unit acquires a battery characteristic and an operation condition of a storage battery device including a plurality of storage batteries. The selection unit selects data values from a data value group of a data item in which variation in data value is caused out of data items included in the battery characteristic and the operation condition acquired by the acquisition unit. The estimation unit estimates, for each of the data values selected by the selection unit, a battery characteristic after operation corresponding to a case where the storage battery device is operated under the operation condition. The battery characteristic is estimated on the basis of the battery characteristic and the operation condition acquired by the acquisition unit. The battery characteristic is estimated by using a digital model capable of reproducing operations and deterioration characteristics of the storage batteries in a simulative manner.

Hereinafter, embodiments of the present invention will be described with reference to the drawings. The configurations of the embodiments described below and the actions and results (effects) caused thereby are merely examples, and are not limited only to the following description.

### First Embodiment

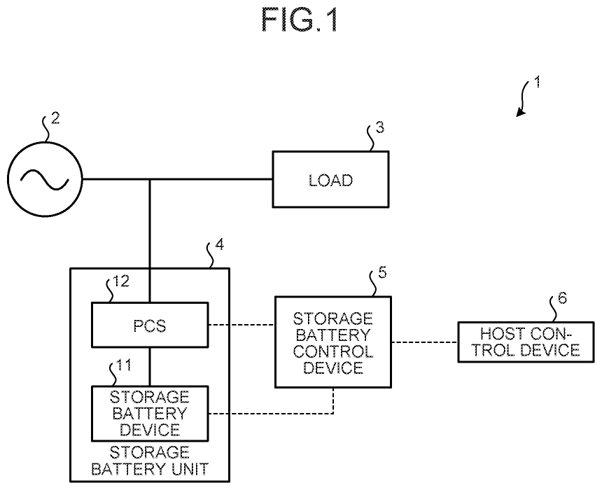

FIG. 1 is a diagram illustrating an example of a configuration of a storage battery system according to a first embodiment. A storage battery system 1 includes a commercial power supply 2, a load 3, a storage battery unit 4, a storage battery control device 5, and a host control device 6.

The commercial power supply 2 supplies power to the storage battery unit 4. The load 3 is a device that consumes power. The load 3 usually operates by being supplied with power from the commercial power supply 2, but when the power supply from the commercial power supply 2 is stopped, the load 3 operates by being supplied with power from the storage battery unit 4.

The storage battery unit 4 charges the commercial power supply 2 with power or supplies power to the load 3. The storage battery control device 5 is an example of a storage battery management device. The storage battery control device 5 controls the storage battery unit 4. Specifically, the storage battery control device 5 controls the charging/discharging operation of a storage battery device 11 included in the storage battery unit 4.

The host control device 6 remotely controls the storage battery control device 5. Specifically, the host control device 6 acquires information indicating a power state and the like from the commercial power supply 2 and the load 3 via a network (not illustrated), and outputs a charge/discharge command value to the storage battery control device 5 on the basis of the acquired information.

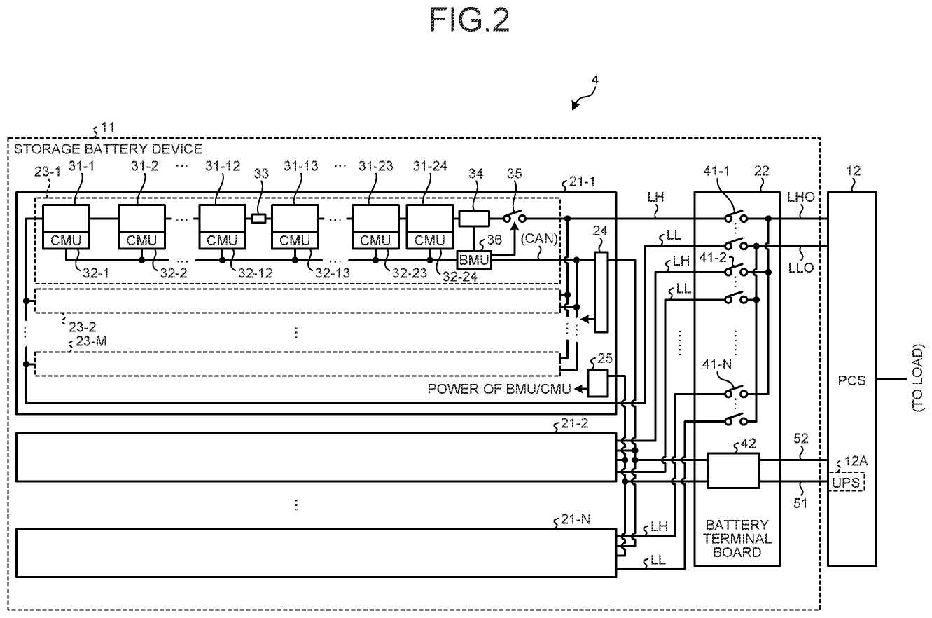

On the basis of the charge/discharge command value input from the host control device 6, the storage battery control device 5 allocates a charging amount or a discharging amount, for example, in units of battery units or cell modules (see FIG. 2) included in the storage battery device 11, and controls the charging/discharging operation of the storage battery device 11.

Although it has been described above that the storage battery unit 4 is operated as a backup power supply, the present invention is similarly applicable in a case where power of the storage battery unit 4 is supplied in addition to power supplied from the commercial power supply 2 at the time of peak shift for power load leveling. The present invention can also be applied to stabilize power quality (voltage, frequency, etc.) in a case where power is generated by renewable energy (energy by sunlight, solar heat, hydraulic power, wind power, biomass, geothermal heat, etc.).

FIG. 2 is a diagram illustrating an example of a configuration of the storage battery unit 4. The storage battery unit 4 mainly includes a storage battery device 11 that stores power, and a power conditioning system (PCS) 12 that converts DC power supplied from the storage battery device 11 into AC power having a desired power quality and supplies the AC power to the load.

The storage battery device 11 mainly includes a plurality of battery boards 21-1 to 21-N (N is a natural number) and a battery terminal board 22 to which the battery boards 21-1 to 21-N are connected. Each of the battery boards 21-1 to 21-N includes a plurality of battery units 23-1 to 23-M (M is a natural number) connected in parallel to each other, a gateway device 24, and a DC power supply device 25 that supplies DC power for operation to a battery management unit (BMU) and a cell monitoring unit (CMU) to be described later.

Each of the battery units 23-1 to 23-M is connected to output power supply lines (output power supply lines; bus) LHO and LLO via a high potential-side power supply line (high potential-side power supply line) LH and a low potential-side power supply line (low potential-side power supply line) LL to supply power to the PCS 12 that is a main circuit.

Since the battery units 23-1 to 23-M have the same configuration, the battery unit 23-1 will be described as an example. The battery unit 23-1 mainly includes a plurality of cell modules 31-1 to 31-24 (in FIG. 2, the number of cell modules is twenty-four), a plurality of CMUs 32-1 to 32-24 (in FIG. 2, the number of CMUs is twenty-four) provided in the cell modules 31-1 to 31-24, respectively, a service disconnect 33 provided between the cell module 31-12 and the cell module 31-13, a current sensor 34, and a contactor 35, and the cell modules 31-1 to 31-24, the service disconnect 33, the current sensor 34, and the contactor 35 are connected in series.

The cell modules 31-1 to 31-24 constitute battery packs by connecting battery cells in series and in parallel. The cell modules 31-1 to 31-24 connected in series constitute a battery pack group.

The battery unit 23-1 includes a BMU 36. A communication line of each of the CMUs 32-1 to 32-24 and an output line of the current sensor 34 are connected to the BMU 36. The BMU 36 controls the entire battery unit 23-1 under the control of the gateway device 24, and controls whether to open or close the contactor 35 on the basis of a result of communication with each of the CMUs 32-1 to 32-24 (voltage data and temperature data to be described later) and a detection result of the current sensor 34.

Next, a configuration of the battery terminal board will be described. The battery terminal board 22 includes board breakers 41-1 to 41-N correspondingly provided to the battery boards 21-1 to 21-N, and a master device 42 configured as a microcomputer that controls the entire storage battery device 11.

The master device 42 is connected to the PCS 12 via a control power line 51 and a control communication line 52. The control power line 51 is provided via an uninterruptible power system (UPS) 12A of the PCS 12. The control communication line 52 is configured as Ethernet (registered trademark) to exchange control data.

Detailed configurations of the cell modules 31-1 to 31-24, the CMUs 32-1 to 32-24, and the BMU 36 will be described.

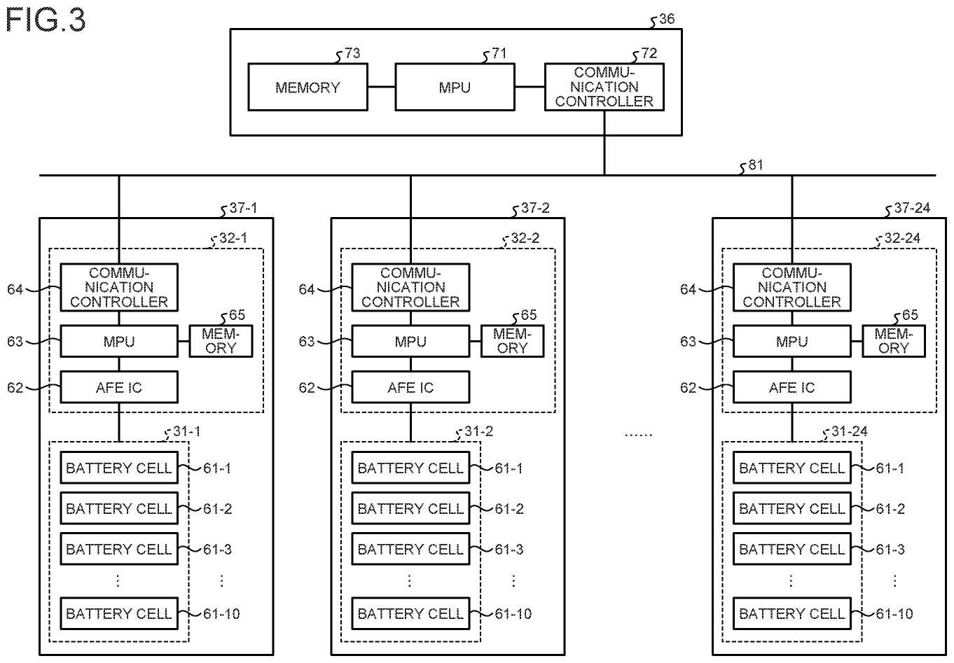

FIG. 3 is a diagram for describing detailed configurations of the cell modules, the CMUs, and the BMU. Each of the cell modules 31-1 to 31-24 includes a plurality of battery cells 61-1 to 61-10 (in FIG. 3, the number of battery cells is ten) connected in series.

Each of the CMUs 32-1 to 32-24 includes a voltage and temperature measuring IC (analog front end IC (AFE-IC)) 62 for measuring voltages of the battery cells 61-1 to 61-10 constituting a corresponding one of the cell modules 31-1 to 31-24 and temperatures at predetermined positions, an MPU 63 that controls an entire corresponding one of the CMUs 32-1 to 32-24, a communication controller 64 that conforms to a controller area network (CAN) standard for performing communications with the BMU 36 via a CAN 81, and a memory 65 that stores voltage data corresponding to the voltages of the respective cells and temperature data.

In addition, the BMU 36 includes an MPU 71 that controls the entire BMU 36, a communication controller 72 that conforms to a CAN standard for performing CAN communication with the CMUs 32-1 to 32-24, and a memory 73 that stores voltage data and temperature data transmitted from the CMUs 32-1 to 32-24.

Note that, in the following description, a combination of each of the cell modules 31-1 to 31-24 and a corresponding one of the CMUs 32-1 to 32-24 will be referred to as a “battery module” (37-1 to 37-24). Each of the battery cells 61-1 to 61-10 will be referred to as a “battery cell”. Moreover, each of the battery units 23-1 to 23-M is referred to as a “battery unit”. In addition, each of the battery unit, the battery module, and the battery cell is an example of the storage battery. Hereinafter, any constituent unit among the storage battery device 11, the battery unit, the battery module, and the battery cell will also be simply referred to as a “storage battery”.

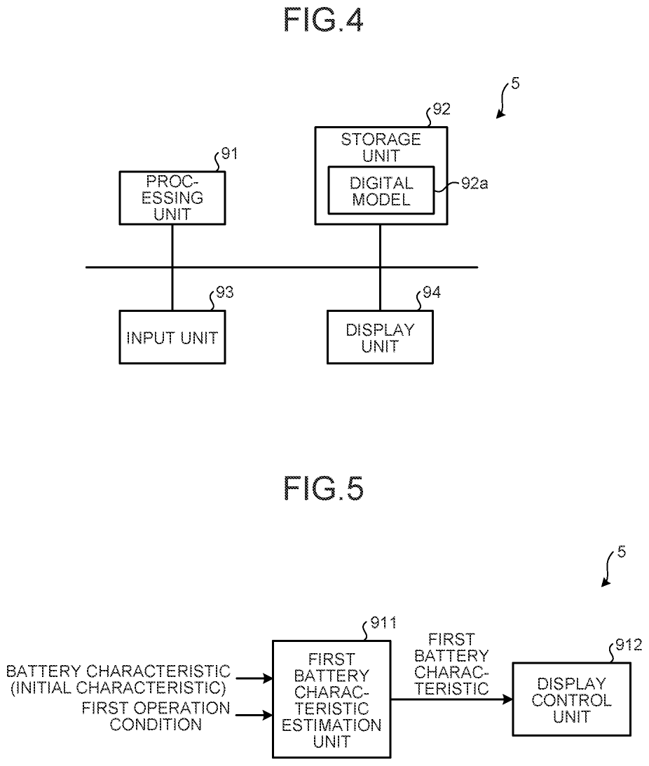

FIG. 4 is a diagram illustrating an example of a hardware configuration of the storage battery control device 5. As illustrated in FIG. 4, the storage battery control device 5 includes a processing unit 91, a storage unit 92, an input unit 93, and a display unit 94. Note that the storage battery control device 5 also includes a communication interface for communicating with other devices (the storage battery unit 4 and the host control device 6), but illustration and description thereof are omitted in order to simplify the description.

The processing unit 91 is a processor such as a central processing unit (CPU), and controls the overall processing of the storage battery control device 5.

The storage unit 92 is a storage device such as a read only memory (ROM), a random access memory (RAM), a hard disk drive (HDD), or a solid state drive (SSD). The storage unit 92 stores various programs and setting information related to the operation of the storage battery control device 5.

In addition, the storage unit 92 stores a digital model 92a that functions to output a battery characteristic such as a battery capacity or a state of health (SOH) of the storage battery at an optional time point as a predicted value by receiving input of the battery characteristic and the operation condition of the storage battery.

The digital model 92a is, for example, data capable of reproducing operation and a deterioration characteristic of the storage battery in a simulative manner, and is implemented by, for example, a simulator program. By reproducing the operation of the storage battery in a simulative manner on the basis of the input battery characteristic and operation condition, the digital model 92a outputs, as a predicted value, a battery characteristic after operation, which corresponds to a case where the storage battery is operated with the battery characteristic and under the operation condition, that is, a time-series variation in battery characteristic.

The battery characteristic to be input to the digital model 92a has data items such as a battery capacity and an internal resistance of the storage battery. The operation condition to be input to the digital model 92a has data items such as a voltage applied to the storage battery, an input/output current of the storage battery, a state of cell (SOC), and a temperature of the storage battery or a temperature around the storage battery (hereinafter also collectively referred to as an environmental temperature). Note that the data items of the battery characteristic and the operation condition described above may be defined for each storage battery, or may be defined for the entire storage battery device 11.

In addition, the battery characteristic output from the digital model 92a represents a battery characteristic after operation, which corresponds to a case where the storage battery is operated under the specified operation condition.

In one example, by inputting a battery characteristic at the time of shipment from the factory (hereinafter also referred to as an initial characteristic) to the digital model 92a, the digital model 92a outputs, as a predicted value, a battery characteristic of the storage battery device 11 from the time of shipment from the factory to a desired point of time. More specifically, the digital model 92a derives a change tendency in battery capacity or internal resistance of the storage battery device 11, which deteriorates over time, as a battery characteristic. That is, the digital model 92a outputs information capable of checking a deterioration state, such as a state of health (SOH), of the storage battery device 11.

In the present embodiment, the battery characteristic and the operation condition are input in units of battery units, battery modules, or battery cells as storage batteries. For example, in a case where the battery characteristic is input in units of battery cells, battery capacities and internal resistances of the battery cells are input to the digital model 92a. In addition, for example, in a case where the operation condition is input in units of battery cells, voltages applied to the battery cells, input/output currents of the battery cells, SOCs, environmental temperatures, and so forth are input to the digital model 92a. In this case, the digital model 92a outputs a battery characteristic during a predetermined period of time or at a predetermined point of time as a predicted value on the basis of the input battery characteristic and operation condition.

Note that the number of digital models 92a stored in the storage unit 92 is not limited to one, and may be two or more. For example, the storage unit 92 may store digital models 92a prepared in constituent units of battery units, battery modules, and battery cells.

The input unit 93 receives various input operations from an operator, converts the received input operations into electric signals, and outputs the electric signals to the processing unit 91. The input unit 93 is implemented by, for example, a keyboard, a mouse, etc.

The display unit 94 displays various types of information and screens under the control of the processing unit 91. The display unit 94 is implemented by, for example, a liquid crystal display or a cathode ray tube (CRT) display.

FIG. 5 is a diagram illustrating an example of a functional configuration of the storage battery control device 5. As illustrated in FIG. 5, the storage battery control device 5 includes a first battery characteristic estimation unit 911 and a display control unit 912.

Part of or all the functional units included in the storage battery control device 5 may have a software configuration implemented by the processing unit 91 executing a program stored in the storage unit 92. In addition, part of or all the functional units included in the storage battery control device 5 may have a hardware configuration implemented by a dedicated circuit included in the processing unit 91 or the like.

The first battery characteristic estimation unit 911 is an example of an acquisition unit, a selection unit, and an estimation unit. The first battery characteristic estimation unit 911 estimates a battery state of the storage battery using the digital model 92a. Specifically, the first battery characteristic estimation unit 911 acquires a battery characteristic and an operation condition of the storage battery, and inputs the acquired battery characteristic and operation condition to the digital model 92a.

The acquisition source of the battery characteristic and the operation condition is not particularly limited, and the battery characteristic and the operation condition may be acquired in various forms. For example, the first battery characteristic estimation unit 911 may acquire a battery characteristic and an operation condition stored in advance in the storage unit 92. In addition, the first battery characteristic estimation unit 911 may acquire a battery characteristic and an operation condition from the storage battery unit 4 and the host control device 6. In addition, the first battery characteristic estimation unit 911 may acquire a battery characteristic and an operation condition input through the input unit 93. Note that, in the present embodiment, the first battery characteristic estimation unit 911 acquires an initial characteristic as a battery characteristic. Hereinafter, the operation condition acquired by the first battery characteristic estimation unit 911 is also referred to as a first operation condition.

The first battery characteristic estimation unit 911 inputs the acquired initial characteristic and first operation condition to the digital model 92a. In response to this, the digital model 92a outputs, as a predicted value, a time-series variation of the initial characteristic that corresponds to a case where the storage battery is operated under the first operation condition. The first battery characteristic estimation unit 911 acquires the predicted value as a first battery characteristic output from the digital model 92a, and outputs the predicted value as an estimation result. Note that the first battery characteristic estimation unit 911 may recursively input the first battery characteristic output from the digital model 92a to the digital model 92a as a changed battery characteristic.

By the way, the initial characteristic and the first operation condition described above are generally different for each storage battery. For example, even though the battery cells are in the same type, variation in data value of the initial characteristics and operation conditions (environmental temperatures, for example) of the battery cells is caused due to differences in arrangement position and manufacturing quality. Since such variations affect a deterioration tendency, it is preferable that a deterioration state of the battery characteristic can be checked in units of storage batteries in managing the storage battery device 11.

Therefore, the first battery characteristic estimation unit 911 selects data values from a data value group of a data item in which variation in data value is caused out of the items included in the initial characteristic and the first operation condition obtained in units of storage batteries such as battery cells. The first battery characteristic estimation unit 911 then estimates a first battery characteristic by using the selected data values.

Specifically, the first battery characteristic estimation unit 911 calculates a variation distribution by statistically analyzing a data value group for each of the items of the battery characteristic and the operation condition. For example, the first battery characteristic estimation unit 911 calculates a distribution indicating variations in environmental temperature by statistically analyzing a data value group of environmental temperature obtained for the battery cells. The type of distribution is not particularly limited, and a normal distribution, a uniform distribution, a triangular distribution, or the like can be used.

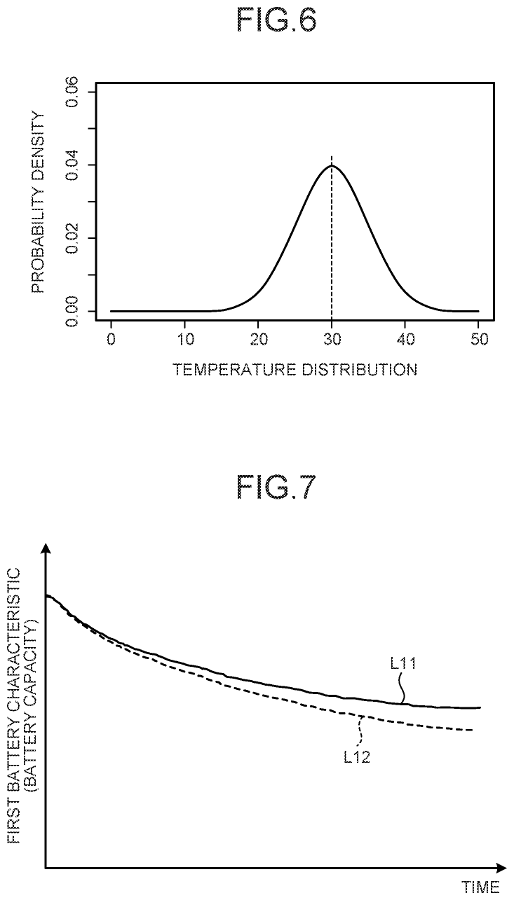

FIG. 6 is a diagram for describing operation of the first battery characteristic estimation unit 911. FIG. 6 illustrates an example of a distribution (normal distribution) calculated for environmental temperatures of the battery cells. The horizontal axis represents temperature distribution (distribution of environmental temperatures), and the vertical axis represents probability density.

After calculating the distribution, the first battery characteristic estimation unit 911 selects data values to be input to the digital model 92a on the basis of the distribution. For example, the first battery characteristic estimation unit 911 specifies data values (temperatures) whose probability density is maximum, minimum, and average, and selects at least two from among these three data values. At this time, the first battery characteristic estimation unit 911 may select data values whose probability density is maximum, minimum, and average from the range of the standard deviation a or the like.

The first battery characteristic estimation unit 911 may select data values for a predetermined data item in which variation in data value is caused, but may select data values for all the data items of the battery characteristic and the operation condition. For example, the first battery characteristic estimation unit 911 may select data values in consideration of variation in any of applied voltage, input/output current, and SOC.

The method of selecting data values performed by the first battery characteristic estimation unit 911 is not limited to the above-described example, and other methods may be used. The first battery characteristic estimation unit 911 may select all data values (temperatures). In addition, the first battery characteristic estimation unit 911 may select data values at intervals of 5° C., 10° C., or the like.

Then, on the basis of the initial characteristic and the first operation condition, the first battery characteristic estimation unit 911 estimates a first battery characteristic for each of the selected data values, which corresponds to a case where the storage battery is operated under the first operation condition. Specifically, when inputting the initial characteristic and the first operation condition to the digital model 92a, the first battery characteristic estimation unit 911 estimates a first battery characteristic for each data value by inputting the selected data values one by one.

Note that, when data values are selected from each of the data items, the first battery characteristic estimation unit 911 estimates first battery characteristics for all combinations of data values of different data items.

Returning to FIG. 5, the display control unit 912 is an example of a display control unit. The display control unit 912 causes the display unit 94 to display the first battery characteristic estimated by the first battery characteristic estimation unit 911. Specifically, the display control unit 912 causes the display unit 94 to display the first battery characteristic estimated for each data value in a comparable state.

FIG. 7 is a diagram illustrating an example of a screen displayed by the display control unit 912. Here, the horizontal axis represents time, and the vertical axis represents magnitude of first battery characteristic (battery capacity). A line L11 depicted with a solid line and a line L12 depicted with a broken line indicate first battery characteristics estimated on the basis of two different data values. The display control unit 912 displays the line L11 and the line L12 in a distinguishable state by making them different in color and line type.

As illustrated in FIG. 7, the display control unit 912 displays the first battery characteristics estimated for the respective data values in a comparable state by arranging the line L11 and the line L12 on the same screen (graph). With this display, an operator of the storage battery control device 5 can easily check a state of variation in deterioration tendency between the storage batteries and a range of battery capacity that the storage batteries can take, by viewing the screen displayed on the display unit 94.

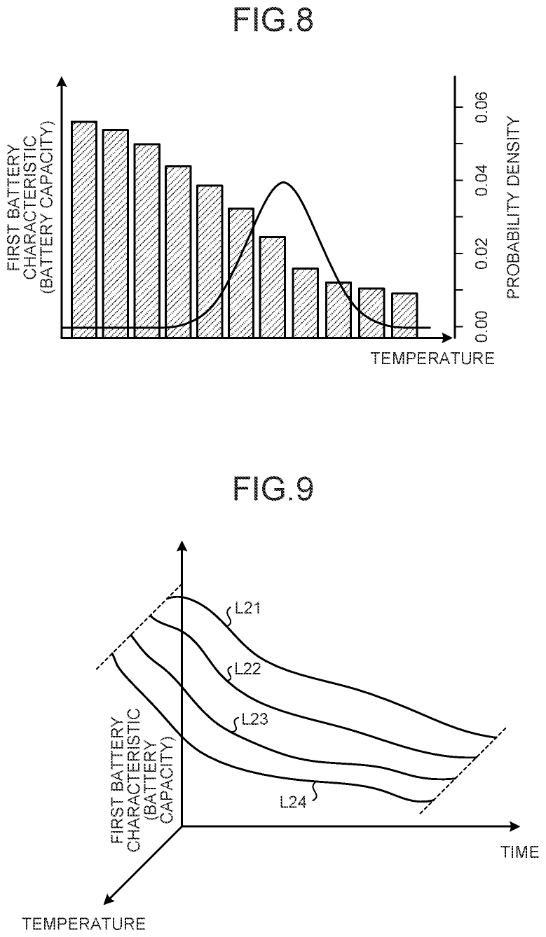

The display form of the first battery characteristics is not limited to the example of FIG. 7. For example, as illustrated in FIG. 8, the display control unit 912 may display a screen on which a relationship between a first battery characteristic and a probability density of a data value in a comparable manner for each data value (temperature).

FIG. 8 is a diagram illustrating another example of a screen displayed by the display control unit 912. Here, the horizontal axis represents temperature. The left vertical axis represents magnitude of first battery characteristic (battery capacity) indicated by a bar graph. In addition, the right vertical axis represents magnitude of probability density indicated by a line graph. Note that FIG. 8 illustrates a first battery characteristics for each temperature zone (5° C. or the like) estimated at a specific time point.

As described above, the display control unit 912 displays a screen showing a data value (temperature) and a first battery characteristic in association with each other while showing a probability density (distribution) for each data value. With this display, an operator of the storage battery control device 5 can easily check a relationship between each temperature zone, a first battery characteristic, and a probability density by viewing the screen displayed on the display unit 94.

The screen displayed by the display control unit 912 is not limited to a two-dimensional graph, and may be a three-dimensional graph. For example, as illustrated in FIG. 9, the display control unit 912 may display a screen that three-dimensionally shows a first battery characteristic calculated for each data value.

FIG. 9 is a diagram illustrating another example of a screen displayed by the display control unit 912. FIG. 9 illustrates a three-dimensional graph in which time, temperature, and first battery characteristic are assigned to three axes orthogonal to each other. Here, lines L21 to L24 are results of estimating four first battery characteristics whose temperature conditions are different, which represent that capacity deteriorations progress in different patterns.

In this manner, the display control unit 912 displays a screen three-dimensionally showing a transition pattern of a first battery characteristic estimated for each data value in a comparable state. With this display, an operator of the storage battery control device 5 can easily compare the transition patterns of the first battery characteristics calculated for the respective data values by viewing the screen displayed on the display unit 94.

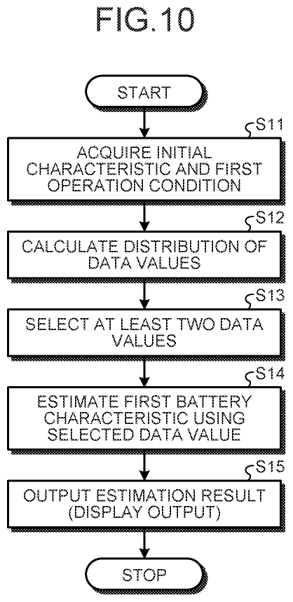

Hereinafter, the operation of the storage battery control device 5 will be described with reference to FIG. 10. FIG. 10 is a diagram illustrating an example of processing executed by the storage battery control device 5.

First, the first battery characteristic estimation unit 911 acquires initial characteristics and first operation conditions of the storage batteries (step S11).

Subsequently, the first battery characteristic estimation unit 911 calculates a distribution on the basis of data values for a data item in which variation in data value is caused out of data items included in the initial characteristics and the first operation conditions acquired in step S11 (step S12). Next, the first battery characteristic estimation unit 911 selects at least two data values on the basis of the distribution calculated in step S12 (step S13).

Subsequently, the first battery characteristic estimation unit 911 estimates a first battery characteristic for each of the data values (step S14) by using the initial characteristics and the first operation conditions acquired in step S11 and the data values selected in step S13.

Subsequently, the display control unit 912 causes the display unit 94 to display the first battery characteristic estimated for each data value in a comparable state on the basis of an estimation result in step S14 (step S15), and ends this processing.

As described above, the storage battery control device 5 selects data values from a data value group of a data item in which variation in data value is caused out of the data items included in the initial characteristics and the first operation conditions of the storage batteries. Then, on the basis of the initial characteristics and the first operation conditions, the storage battery control device 5 estimates first battery characteristics for each of the selected data values, and causes the display unit 94 to display each of the estimated first battery characteristics in a comparable state.

As a result, the storage battery control device 5 can present the first battery characteristics in a comparable state on the basis of the data values between which variation has occurred. Therefore, an operator of the storage battery control device 5 can check a state of variation in deterioration tendency between the storage batteries.

In addition, the storage battery control device 5 estimates battery characteristics by using the digital model 92a that is capable of reproducing operations and deterioration characteristics of the storage batteries in a simulative manner Therefore, it is possible to cope with various operation conditions and efficiently estimate battery characteristics.

Note that, although it has been described in the above-described embodiment that the estimation result (first battery characteristics) of the first battery characteristic estimation unit 911 is displayed (output) on the display unit 94, the output destination of the estimation result is not limited thereto. For example, the storage battery control device 5 may transmit (output) the estimation result of the first battery characteristic estimation unit 911 to the host control device 6 or the like.

### Second Embodiment

Next, a second embodiment will be described. The same reference signs are given to the same components as those of the storage battery control device 5 in the above-described embodiment, and the description thereof will be appropriately omitted.

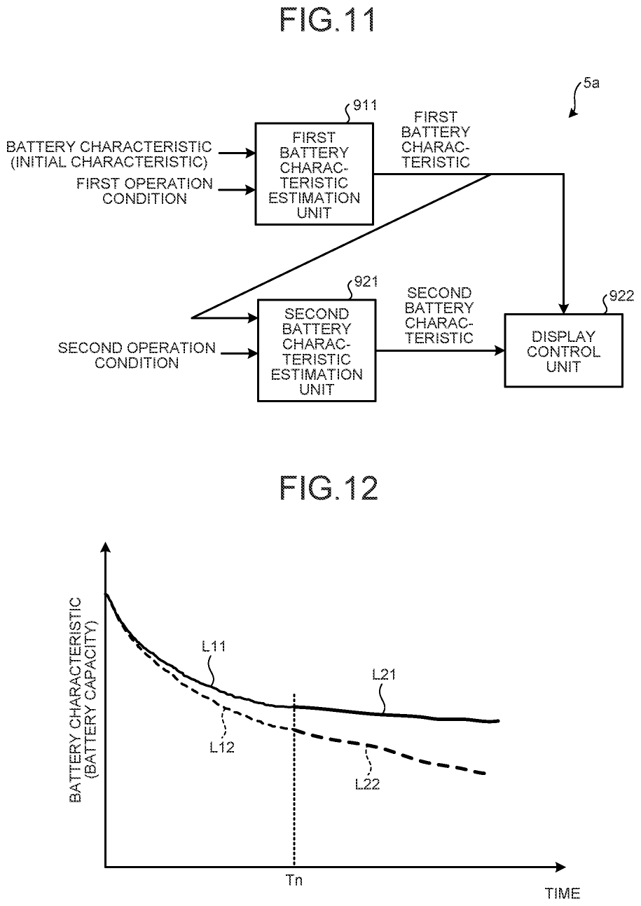

FIG. 11 is a diagram illustrating an example of a functional configuration of a storage battery control device 5a according to the second embodiment. Note that a hardware configuration of the storage battery control device 5a is similar to the above-described configuration as illustrated in FIG. 4.

As illustrated in FIG. 11, the storage battery control device 5a includes, as functional units, a first battery characteristic estimation unit 911, a second battery characteristic estimation unit 921, and a display control unit 922. The first battery characteristic estimation unit 911 and the second battery characteristic estimation unit 921 are connected in multiple stages. Note that the first battery characteristic estimation unit 911 is an example of a first estimation unit. In addition, the second battery characteristic estimation unit 921 is an example of a second estimation unit.

Similarly to the first battery characteristic estimation unit 911, the second battery characteristic estimation unit 921 estimates a battery state of the storage battery device 11 by using the digital model 92a. Specifically, the second battery characteristic estimation unit 921 acquires the first battery characteristics derived by the first battery characteristic estimation unit 911 and second operation characteristics, and inputs the first battery characteristics and the second operation characteristics to digital model 92a.

As described in the first embodiment, the first battery characteristics are derived for each of data values between which variation has occurred. In addition, the second operation conditions indicate future operation conditions after a time point at which the first operation conditions are applied. The second battery characteristic estimation unit 921 estimates a future battery characteristic to be obtained after the first battery characteristic estimated by the first battery characteristic estimation unit 911, as a second battery characteristic for each first battery characteristic (that is, for each data value).

For example, the first battery characteristic estimation unit 911 derives first battery characteristics indicating time-series variations in initial characteristics from operating the storage battery device 11 to the present (current time point), on the basis of the initial characteristics and the first operation conditions. On the other hand, the second battery characteristic estimation unit 921 derives second battery characteristics indicating battery characteristics from the present to an optional time point in the future, on the basis of the first battery characteristics and the second operation conditions indicating future operation conditions.

Note that the second operation conditions may be stored in advance in the storage unit 92 or the like, or may be input via the input unit 93. In addition, the first battery characteristic estimation unit 911 and the second battery characteristic estimation unit 921 may use the same digital model 92a or different digital models 92a. Even in a case where the first battery characteristic estimation unit 911 and the second battery characteristic estimation unit 921 use the same digital model 92a, parameters related to the operation of estimating battery characteristics may be differentiated between the first battery characteristic estimation unit 911 and the second battery characteristic estimation unit 921.

The display control unit 922 causes the display unit 94 to display the first battery characteristics estimated by the first battery characteristic estimation unit 911 and the second battery characteristics estimated by the second battery characteristic estimation unit 921. Specifically, the display control unit 922 displays the first battery characteristics and the second battery characteristics estimated for the respective data values in a comparable state.

FIG. 12 is a diagram illustrating an example of a screen displayed by the display control unit 922. Here, the horizontal axis represents time, and the vertical axis represents magnitude of battery characteristic (battery capacity).

A line L11 depicted with a solid line and a line L12 depicted with a broken line indicate first battery characteristics estimated by using two different data values. More specifically, the first battery characteristic represents a transition of battery capacity from a time of starting the operation to a time Tn corresponding to the current time point.

A line L21 indicates a second battery characteristic estimated on the basis of the first battery characteristic indicated by the line L11. The second battery characteristic indicated by the line L21 represents a transition of battery capacity after the time Tn. The display control unit 922 displays a series of line graphs by connecting the line L11 and the line L21 estimated on the basis of the same data value at the time Tn.

A line L22 indicates a second battery characteristic estimated on the basis of the first battery characteristic indicated by the line L12. The second battery characteristic indicated by the line L22 represents a transition of battery capacity after the time Tn. The display control unit 922 displays a series of line graphs by connecting the line L12 and the line L22 estimated on the basis of the same data value at the time Tn.

As described above, the display control unit 922 display, in a comparable state, each set including a first battery characteristic and a second battery characteristic estimated on the basis of the same data value. With this display, an operator of the storage battery control device 5a can easily check a state of variation in deterioration tendency between the storage batteries and a range of battery capacity that the storage batteries can take by viewing the screen displayed on the display unit 94.

Note that the screen displayed by the display control unit 922 is not limited to the example of FIG. 12. For example, the display control unit 922 may display a screen showing first battery characteristics and second battery characteristics in the above-described forms as illustrated in FIGS. 8 and 9.

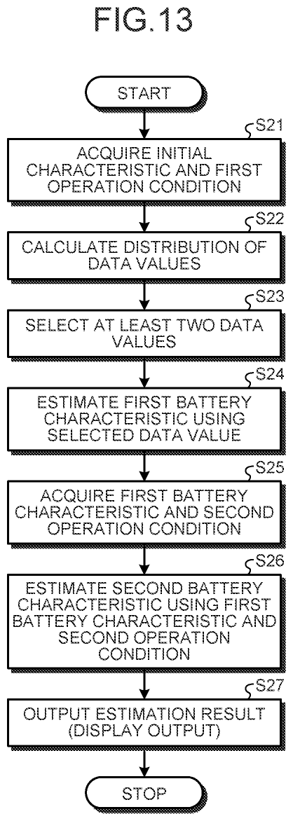

Hereinafter, the operation of the storage battery control device 5a will be described with reference to FIG. 13. FIG. 13 is a diagram illustrating an example of processing executed by the storage battery control device 5a. Note that steps S21 to S24 are similar to steps S11 to S14 described with reference to FIG. 10, and thus, the description thereof is omitted.

After the first battery characteristics are estimated in step S24, the second battery characteristic estimation unit 921 acquires the first battery characteristics and the second operation conditions (step S25).

Subsequently, the second battery characteristic estimation unit 921 estimates the second battery characteristics by using the first battery characteristics and the second operation conditions (step S26). Note that the second battery characteristic estimation unit 921 estimates a second battery characteristic for each of the first battery characteristics acquired in step S25.

Subsequently, the display control unit 922 causes the display unit 94 to display, in a comparable state, each set including a first battery characteristic and a second battery characteristic estimated on the basis of the same data value on the basis of estimation results in steps S24 and S26 (step S27), and ends this processing.

As described above, the storage battery control device 5a selects data values from a data value group of a data item in which variation in data value is caused out of the data items included in the initial characteristics and the first operation conditions of the storage batteries. The storage battery control device 5a estimates a first battery characteristic for each of the data values selected on the basis of the initial characteristics and the first operation conditions. In addition, the storage battery control device 5a estimates future second battery characteristics to be obtained after the first battery characteristics in time series, on the basis of the first battery characteristics and second operation conditions. Then, the storage battery control device 5a displays, in a comparable state, each set including a first battery characteristic and a second battery characteristic estimated on the basis of the same data value.

As a result, the storage battery control device 5a can present the first battery characteristic and the second battery characteristic in a comparable state on the basis of each of the data values between which variation has occurred. Therefore, an operator of the storage battery control device 5a can check a state of variation in deterioration tendency between the storage batteries.

Note that, in the above-described embodiment, the estimation unit is constituted by providing the first battery characteristic estimation unit 911 and the second battery characteristic estimation unit 921 in multiple stages, but the estimation unit may be constituted by the first battery characteristic estimation unit 911 alone (or the second battery characteristic estimation unit 921 alone).

Specifically, the first battery characteristic estimation unit 911 can derive an estimation result similar to that from the above-described configuration in FIG. 11 by recursively inputting the first battery characteristics estimated to itself together with second operation conditions.

In the above-described embodiment, the second battery characteristic estimation unit 921 does not perform selection processing of data values. However, the present invention is not limited thereto, and the second battery characteristic estimation unit 921 may perform the selection processing of data values similarly to the first battery characteristic estimation unit 911. For example, when the first battery characteristics and the second operation conditions output by the first battery characteristic estimation unit 911 include a data item in which variation in data value is caused, the second battery characteristic estimation unit 921 selects data values from the data value group of the data item and estimates second battery characteristics.

It has been described in the above-described embodiment that the estimation results (first battery characteristics and second battery characteristics) of the first battery characteristic estimation unit 911 and the second battery characteristic estimation unit 921 are displayed (output) on the display unit 94. However, the output destination of the estimation results is not limited thereto. For example, the storage battery control device 5a may transmit (output) the estimation results of the first battery characteristic estimation unit 911 and the second battery characteristic estimation unit 921 to the host control device 6 or the like.

### Third Embodiment

Next, a third embodiment will be described. The same reference signs are given to the same components as those of the storage battery control device 5(5a) in the above-described embodiment, and the description thereof will be appropriately omitted.

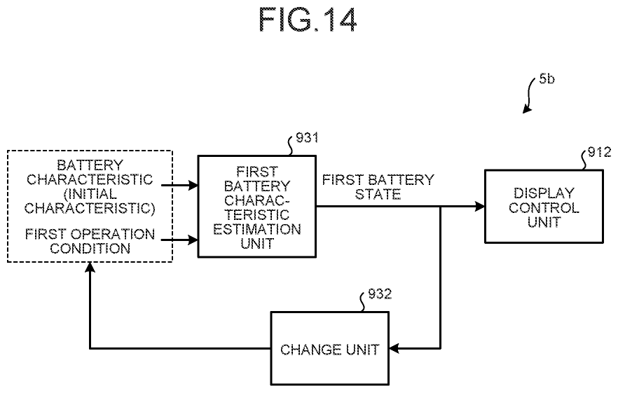

FIG. 14 is a diagram illustrating an example of a functional configuration of a storage battery control device 5b according to the third embodiment. Note that a hardware configuration of the storage battery control device 5b is similar to that illustrated in FIG. 4.

As illustrated in FIG. 14, the storage battery control device 5b includes, as functional units, a first battery characteristic estimation unit 931, a change unit 932, and a display control unit 912.

The first battery characteristic estimation unit 931 has the same function as the first battery characteristic estimation unit 911. In addition, the first battery characteristic estimation unit 931 may estimate a battery state related to the first battery characteristic (hereinafter also referred to as a first battery state) together with the first battery characteristic. Specifically, the first battery characteristic estimation unit 931 outputs a first battery state including data items such as an environmental temperature, an applied voltage, an input/output current, and an SOC, which are used when the digital model 92a calculates the first battery characteristic (a battery capacity or an internal resistance) at each time point. Note that the above-described data items of the first battery state may be defined for each storage battery, or may be defined for the entire storage battery device 11.

The change unit 932 changes the battery characteristic or the first operation condition to be input to the first battery characteristic estimation unit 931 on the basis of an estimation result of the first battery characteristic estimation unit 931 and a predetermined target value.

Specifically, the change unit 932 compares the first battery characteristic estimated by the first battery characteristic estimation unit 931 with a battery characteristic as the target value. In a case where a difference between them exceeds a threshold value, the change unit 932 changes the battery characteristic (initial characteristic) or the first operation condition to be input to the first battery characteristic estimation unit 931 in accordance with the difference amount. The change unit 932 repeatedly changes the battery characteristic or the first operation condition until the difference from the target value becomes equal to or smaller than the threshold value.

Note that the comparison is not limited to be performed on the first battery characteristic alone, and the first battery state may be compared with a target value. In addition, the first battery characteristic estimation unit 931 can change one or both of the battery characteristic and the first operation condition, and may be configured to change them that are designated via the input unit 93. In addition, although an item to be changed by the first battery characteristic estimation unit 931 is not particularly limited, an item designated via the input unit 93 or the like may be changed. The amount of change performed by the first battery characteristic estimation unit 931 is not particularly limited, and for example, the amount of change may be increased or decreased by a predetermined amount each time, or the amount of change may be designated via the input unit 93 or the like.

The display control unit 912 causes the display unit 94 to display the first battery characteristic derived by the first battery characteristic estimation unit 931. In addition, the display control unit 912 may cause the display unit 94 to display a first battery characteristic when the difference between the first battery characteristic and the target value becomes equal to or smaller than the threshold value in the same display form as in the above-described embodiment by cooperating with the change unit 932.

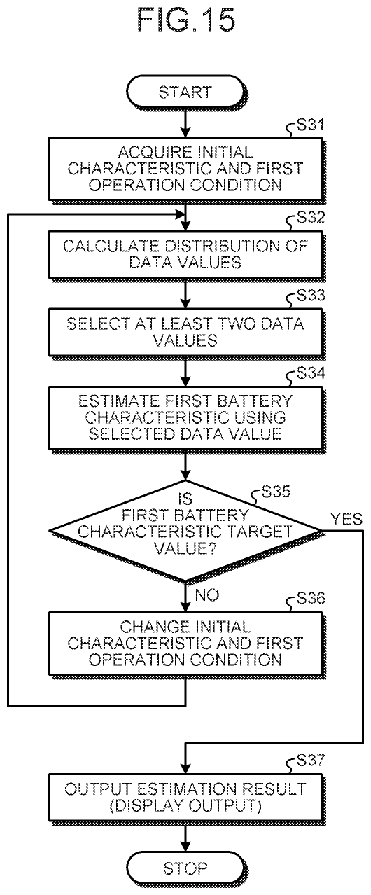

Hereinafter, the operation of the storage battery control device 5b will be described with reference to FIG. 15. FIG. 15 is a diagram illustrating an example of processing executed by the storage battery control device 5b. Note that steps S31 to S34 are similar to steps S11 to S14 described with reference to FIG. 10, and thus, the description thereof is omitted.

After the first battery characteristic (or the first battery state) is estimated in step S34, the change unit 932 compares the first battery characteristic with a target value and determines whether a difference amount is equal to or smaller than a threshold value (step S35). In response to determining that the difference amount exceeds the threshold value (step S35; No), the change unit 932 changes the data value included in the initial characteristic or the first operation condition input to the first battery characteristic estimation unit 931 (step S36), and returns the processing to step S32.

On the other hand, in response to determining in step S35 that the difference amount is equal to or smaller than the threshold value (step S35; Yes), the change unit 932 shifts the processing to step S37. Subsequently, the display control unit 912 causes the display unit 94 to display the first battery characteristic estimated for each data value in a comparable state on the basis of an estimation result in step S34 (step S37), and ends this processing.

As described above, when the first battery characteristic or the first battery state is different from the target value, the storage battery control device 5b changes the battery characteristic or the first operation condition in accordance with the difference amount.

As a result, the storage battery control device 5b can bring the first battery characteristic or the first battery state close to the target value, and thus can specify a battery characteristic or a first operation condition for achieving a desired first battery characteristic or first battery state.

### First Modification

In the storage battery control device 5b described with reference to FIG. 14, the change unit 932 is provided in the first battery characteristic estimation unit 931 that estimates first battery characteristics. However, the present invention is not limited thereto, and the change unit 932 may be provided in the second battery characteristic estimation unit 921 that estimates second battery characteristics.

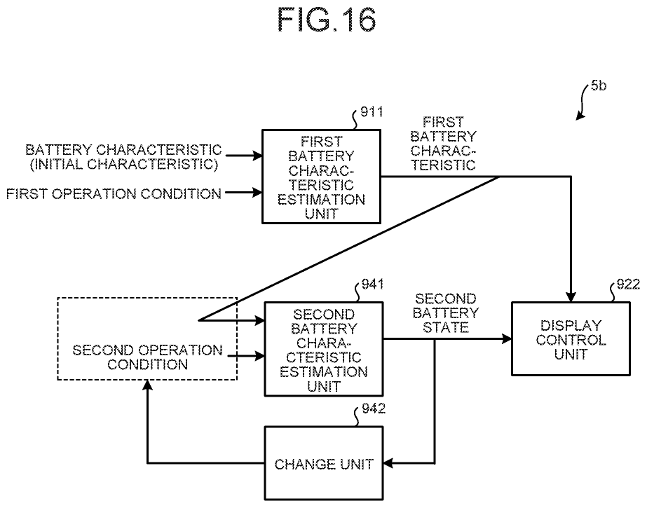

For example, the storage battery control device 5b may have a configuration illustrated in FIG. 16. FIG. 16 is a diagram illustrating an example of a configuration of a storage battery control device 5b according to the present modification.

As illustrated in FIG. 16, the storage battery control device 5b has a configuration in which the second battery characteristic estimation unit 921 in the configuration described in FIG. 11 is replaced with a second battery characteristic estimation unit 941, and a change unit 942 is added.

The second battery characteristic estimation unit 941 may estimate a battery state related to the second battery characteristic (hereinafter also referred to as a second battery state) together with the second battery characteristic. Specifically, the second battery characteristic estimation unit 941 outputs, as a second battery state, parameter values such as a battery temperature, a battery voltage, a battery current, and an SOC, which are used when the digital model 92a calculates the second battery characteristic (a battery capacity or an internal resistance) at each time point.

The change unit 942 changes the second operation condition input to the second battery characteristic estimation unit 941 on the basis of an estimation result of the second battery characteristic estimation unit 941 and a target value.

Specifically, the change unit 942 compares, with the target value, the second battery characteristic or the second battery state estimated by the second battery characteristic estimation unit 941. The change unit 942 then changes the second operation condition to be input to the second battery characteristic estimation unit 941 in accordance with a difference amount when the difference exceeds a threshold value. The change unit 942 repeatedly changes the second operation condition until the difference from the target value becomes equal to or smaller than the threshold value.

Note that, not limited to the second operation condition, the change unit 942 may change the battery characteristic or the first operation condition input to the first battery characteristic estimation unit 911.

As described above, when the second battery characteristic or the second battery state is different from the target value, the storage battery control device 5b according to the present modification changes the second operation condition or the like in accordance with the difference amount.

As a result, the storage battery control device 5b can bring the second battery characteristic or the second battery state close to the target value, and thus can specify a second operation condition for achieving a desired second battery characteristic or second battery state.

Although some embodiments of the present invention and a modification thereof have been described above, the above-described embodiments and modification thereof are merely examples, and are not intended to limit the scope of the invention. The above-described embodiments can be implemented in various forms, and various omissions, substitutions, combinations, and changes can be made to the above-described embodiments without departing from the gist of the invention. The above-described embodiments and modifications thereof fall within the scope and spirit of the invention, and fall within the scope of the invention set forth in the claims and the equivalent thereof.

1. A storage battery management device comprising a hardware processor connected to a memory, the hardware processor being configured to function as:
an acquisition unit to acquire a battery characteristic and an operation condition of a storage battery device including a plurality of storage batteries;
a selection unit to select data values from a data value group of a data item in which variation in data value is caused out of data items included in the battery characteristic and the operation condition acquired by the acquisition unit; and
an estimation unit to estimate, for each of the data values selected by the selection unit, a battery characteristic after operation corresponding to a case where the storage battery device is operated under the operation condition, the battery characteristic being estimated on the basis of the battery characteristic and the operation condition acquired by the acquisition unit, the battery characteristic being estimated by using a digital model capable of reproducing operations and deterioration characteristics of the storage batteries in a simulative manner.

2. The storage battery management device according to claim 1, wherein the hardware processor is configured to further function as a display control unit to cause a display device to display the battery characteristic estimated by the estimation unit in a comparable state.

3. The storage battery management device according to claim 1, wherein
the acquisition unit acquires the battery characteristic estimated by the estimation unit as a new battery characteristic and acquires a new operation condition, and
the estimation unit estimates, for each of the data values selected by the selection unit, a battery characteristic after operation corresponding to a case where the storage battery device is operated under the newly acquired operation condition on the basis of the newly acquired battery characteristic and the newly acquired operation condition.

4. The storage battery management device according to claim 3, wherein
the estimation unit includes a first estimation unit and a second estimation unit in multiple stages to estimate a battery characteristic, and
the second estimation unit estimates a future battery characteristic to be obtained after a time point of a battery characteristic estimated by the first estimation unit.

5. The storage battery management device according to claim 1, wherein the selection unit selects the data values on the basis of a distribution of the data value group.

6. The storage battery management device according to claim 1, wherein the selection unit selects at least two data values from among a maximum value, a minimum value, and an average value of the data values.

7. The storage battery management device according to claim 1, wherein the battery characteristic includes one or both of a battery capacity and an internal resistance, as data items representing a battery characteristic of the entire storage battery device or a battery characteristic of each of the storage batteries.

8. The storage battery management device according to claim 1, wherein the operation condition includes one or all of a temperature, an applied voltage, an applied current, and a charging rate, as data items representing an operation condition of the overall storage battery device or an operation condition of each of the storage batteries.

9. The storage battery management device according to claim 2, wherein the display control unit causes the display device to display a distribution of the battery characteristics estimated for the respective data values.

10. The storage battery management device according to claim 2, wherein the display control unit causes the display device to display each of the battery characteristics estimated by the estimation unit in a distinguishable state.

11. The storage battery management device according to claim 1, wherein the hardware processor is configured to further function as a change unit to change the battery characteristic or the operation condition to be input to the estimation unit in accordance with a difference between the battery characteristic estimated by the estimation unit and a predetermined target value.

12. The storage battery management device according to claim 11, wherein
the estimation unit estimates the battery characteristic and estimates a battery state of the entire storage battery device or a battery state of each of the storage batteries related to the battery characteristic, and
the change unit changes the battery characteristic or the operation condition input to the estimation unit in accordance with a difference between the battery state and the predetermined target value.

13. The storage battery management device according to claim 12, wherein the battery state includes one or all of a temperature, an applied voltage, an applied current, and a charging rate of the entire storage battery device or the storage battery.

14. A storage battery management method comprising:
acquiring a battery characteristic and an operation condition of a storage battery device including a plurality of storage batteries;
selecting data values from a data value group of a data item in which variation in data value is caused out of data items included in the battery characteristic and the operation condition acquired by the acquiring; and
estimating, for each of the data values selected by the selecting, a battery characteristic after operation corresponding to a case where the storage battery device is operated under the operation condition, the battery characteristic being estimated on the basis of the battery characteristic and the operation condition acquired by the acquiring, the battery characteristic being estimated by using a digital model capable of reproducing operations and deterioration characteristics of the storage batteries in a simulative manner.

15. The storage battery management method according to claim 14, further comprising causing a display device to display the estimated battery characteristic in a comparable state.

16. The storage battery management method according to claim 15, wherein the causing is performed by causing the display device to display a distribution of the battery characteristics estimated for the respective data values.

17. The storage battery management method according to claim 15, wherein the causing is performed by causing the display device to display each of the battery characteristics estimated by the estimation unit in a distinguishable state.
